(19) United States
(12) Patent Application Publication
(10) Pub. No.: US 2014/0097852 A1
(43) Pub. Date: Apr. 10, 2014

(54) VOLTAGE MONITORING DEVICE

(71) Applicant: DENSO CORPORATION, Kariya-city (JP)

(72) Inventor: Hayato MIZOGUCHI, Takahama-shi (JP)

(73) Assignee: DENSO CORPORATION, Kariya-city (JP)

(21) Appl. No.: 14/046,300

(22) Filed: Oct. 4, 2013

(30) Foreign Application Priority Data
Oct. 9, 2012 (JP) 2012-224223

(51) Int. Cl. G01R 31/36

(52) U.S. Cl. CPC G01R 31/362
USPC 324/434

(57) ABSTRACT

A voltage monitoring device monitors voltage of a battery pack having a plurality of battery cells connected in series. This device is provided with a capacitor circuit including a pair of independent terminals, a plurality of capacitors connected in series between the pair of independent terminals, and at least one connecting terminal arranged between adjacent capacitors of the capacitors. In the device, first input-side switches connect the pair of independent terminals to first electrode terminals of the battery cells, and second input-side switches connect the connecting terminal to second electrode terminals among the electrode terminals other than the first electrode terminal. The first electrode terminals are arranged at a predetermined interval that covers a predetermined number of the electrode terminals corresponding to the number of the connecting terminal. The number of the second input-side switches is less than the number of the electrode terminals other than the first electrode terminals.

### CROSS-REFERENCE TO RELATED APPLICATION

This application is based on and claims the benefit of priority from earlier Japanese Patent Application No. 2012-224223 filed Oct. 9, 2012, the description of which is incorporated herein by reference.

### BACKGROUND

1. Technical Field

The present invention relates to a voltage monitoring device using a flying capacitor method, which monitors voltage of a battery pack by using a plurality of capacitors, the battery pack including a plurality of serially connected battery cells.

2. Related Art

In related art, a device using capacitors (also called a voltage monitoring device using a flying capacitor method) is known as a voltage monitoring device for monitoring the voltage of a battery pack, such as a high-voltage battery installed in hybrid cars or electric cars, in which a number of battery cells are connected in series (e.g., refer to patent document JP-A-2002-289263).

JP-A-2002-289263 discloses a technique for parallelly detecting the voltages of two adjacent battery cells in a battery pack, by using a pair of serially connected capacitors (first and second capacitors). This technique is also called a double flying capacitor method.

Specifically, the voltage monitoring device disclosed in JP-A-2002-289263 includes: (i) a plurality of input-side switches that connect the 4m−1^{th} (m is a positive integer) electrode terminals among the electrode terminals of the battery cells to an independent terminal of the first capacitor; (ii) a plurality of input-side switches that connect the 4m+1^{th} electrode terminals to an independent terminal of the second capacitor; and (iii) a plurality of input-side switches that connect the 2m^{th} electrode terminals to a connecting terminal of the first and second capacitors.

When the input-side switches are sequentially turned on, the voltages of the battery cells are ensured to be applied to the capacitors. A battery pack in which N battery cells are connected in series has N+1 electrode terminals. Accordingly, the battery pack will need N+1 input-side switches.

A voltage monitoring device using a flying capacitor method may be configured such that, as disclosed in JP-A-2002-289263, input-side switches are connected to all of the electrode terminals of the battery cells. However, in this case, the number of the input-side switches is increased and thus the number of parts of the components of the voltage monitoring device is also increased. In particular, the input-side switches connected to the electrode terminals of the battery cells are each required to be configured by an expensive element having high withstand-voltage properties so as not to cause a failure when overvoltage, for example, is caused on a battery pack side. When the number of the input-side switches is large, the cost of the entire voltage monitoring device is increased accordingly.

### SUMMARY

It is thus desired to provide a voltage monitoring device that uses a flying capacitor method, which is able to reduce the number of parts.

According to an exemplary aspect of the present disclosure, there is provided a voltage monitoring device for monitoring voltage of a battery pack using a flying capacitor method. The battery pack includes a plurality of battery cells that are connected in series to one another.

The voltage monitoring device includes a capacitor circuit, a plurality of first input-side switches, a plurality of second input-side switches, input-side switch control means, voltage detecting means, a plurality of output-side switches and output-side switch control means.

The capacitor circuit includes a pair of independent terminals, a plurality of capacitors connected in series to each other between the pair of independent terminals, and at least one connecting terminal arranged between adjacent capacitors of the plurality of capacitors.

The plurality of first input-side switches connect the pair of independent terminals to first electrode terminals among electrode terminals of the plurality of battery cells. The first electrode terminals are arranged at a predetermined interval that covers a predetermined number of the electrode terminals corresponding to the number of connecting terminals.

The plurality of second input-side switches connect the connecting terminal to the electrode o second electrode terminals among the electrode terminals other than the first electrode terminal. The number of the second input-side switches is less than the number oft the electrode terminals other than the first electrode terminals.

The input-side switch control means controls the plurality of first input-side switches and the plurality of second input-side switches so as to be turned on in a predetermined sequence, thereby applying voltage of at least one of the plurality of battery cells to the plurality of capacitors.

The voltage detecting means includes a plurality of input terminals and detects voltage between the plurality of input terminals.

The plurality of output-side switches connect the plurality of input terminals to the pair of independent terminals and the connecting terminal.

The output-side switch control means controls the plurality of output-side switches so as to be turned on in a predetermined sequence to connect the plurality of input terminals to at least two of the connecting terminal and the pair of independent terminals, thereby applying stored voltage of at least one of the plurality of capacitors to the plurality of input terminals of the voltage detecting means.

With this configuration, the total number of the first and second input-side switches that require high withstand-voltage properties is less than the total number of the electrode terminals of the battery cells. Thus, the number of parts can be reduced in the components configuring the voltage monitoring device that uses a flying capacitor method.

The battery cells include the battery cells to which the second input-side switches are not connected (unconnected battery cells). The voltage of each of such unconnected battery cells may be collectively detected together with the voltage of the battery cell close to the unconnected battery cell. For example, by turning on the first input-side switches connected to the electrode terminal of the battery cell close to the unconnected battery cell, the voltage of a battery block that includes the unconnected battery cell and the battery cell close to the unconnected battery cell is applied to the independent terminals of the capacitors. Then, the voltage detecting means may be used to detect the voltage applied to the capacitors, i.e. the voltage of the battery block that includes the unconnected battery cell and the battery cell close to the unconnected.

### BRIEF DESCRIPTION OF DRAWINGS

In the accompanying drawings:

FIG. 1 is a schematic diagram showing a monitoring system that includes a voltage monitoring device according to a first embodiment of the present invention;

FIG. 2 is a schematic diagram showing a monitoring system that includes a voltage monitoring device according to a second embodiment of the present invention;

FIG. 3 is a schematic diagram showing a monitoring system that includes a voltage monitoring device according to a modification of the present invention; and

FIG. 4 is a schematic diagram showing a monitoring system that includes a voltage monitoring device according to another modification of the present invention.

### DESCRIPTION OF EMBODIMENTS

With reference to the accompanying drawings, hereinafter are described some embodiments of the present invention. In the embodiments provided below, identical or similar components are given the same reference numerals for the sake of omitting or simplifying explanation.

### First Embodiment

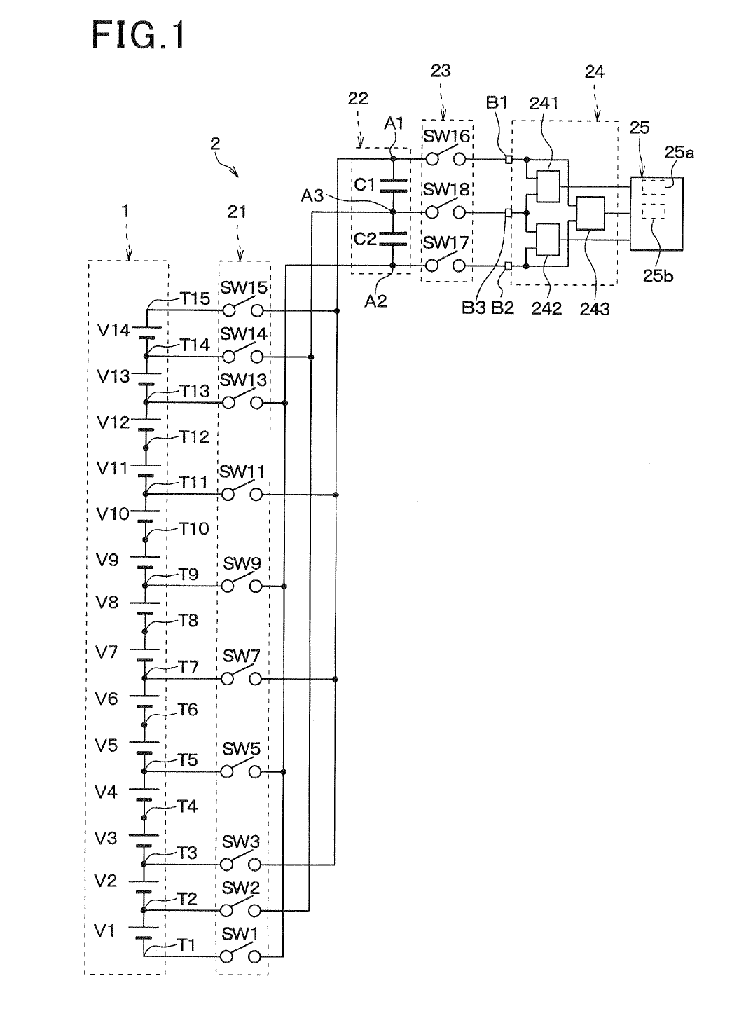

Referring to FIG. 1, a first embodiment of the present invention is described. In the first embodiment, a voltage monitoring device 2 of the present invention is applied to a system for monitoring in-vehicle high-voltage batteries that configure a battery pack 1. FIG. 1 shows is a monitoring system that includes the voltage monitoring device 2 according to the first embodiment.

As shown in FIG. 1, the monitoring system according to the present embodiment includes, as principal elements, the battery pack 1 and the voltage monitoring device 2 that uses a flying capacitor method.

For example, the battery pack 1 supplies electrical power to an electric motor (motor used for a vehicle to run) via an inverter. The battery pack 1 of the present embodiment includes a serial connection of n (fourteen in the present embodiment) battery cells V1 to V14, i.e. a minimum unit for performing charge and discharge. The battery cells V1 to V14 may be lithium ion batteries, lead batteries, or the like, that can perform charge and discharge.

The battery pack 1 configured as described above is connected to the voltage monitoring device 2 via a plurality of detecting lines which are connected to electrode terminals (positive terminals and negative terminals) T1 to T15 of the battery cells V1 to V14.

The electrode terminals T1 to T15 of the battery cells V1 to V14 include the electrode terminals T2 to T14 arranged in between the individual battery cells, the positive terminal T15 of the highest-voltage-side battery cell (high-voltage-side cell) V14 and the negative terminal T1 of the lowest-voltage-side battery cell (low-voltage-side cell) V1. When the number of the battery cells configuring the battery pack 1 is n, the number of the electrode terminals of the battery cells is n+1. In other words, the number of the electrode terminals T1 to T15 is larger, by one, than the number of the battery cells V1 to V14.

Hereinafter, the voltage monitoring device 2 according to the present embodiment is described. The voltage monitoring device 2 of the present embodiment uses a double flying capacitor method. Specifically, in the voltage monitoring device 2, a pair of serially connected capacitors C1 and C2 is used to detect the voltages of the battery cells V1 to V14.

The voltage monitoring device 2 includes an input-side connection switching circuit 21, a capacitor circuit 22, an output-side connection switching circuit 23 that configures an output-side connection switching means, a voltage detecting circuit 24 that configures a voltage detecting means, and a microcomputer 25.

The input-side connection switching circuit 21 sequentially connects the electrode terminals T1 to T15 of the battery cells V1 to V14 to independent terminals A1 and A2 of the pair of capacitors C1 and C2, respectively, and a connecting terminal A3 arranged between the pair of capacitors C1 and C2 in the capacitor circuit 22. With the activation of the input-side connection switching circuit 21, the voltage of at least one of the battery cells V1 to V14 is ensured to be applied (charged) to the capacitors C1 and C2.

In the present embodiment, the input-side connection switching circuit 21 includes a plurality of first input-side switches SWi (i: odd number selected from 1 to 15) to be connected to the independent terminals A1 and A2 of the capacitors C1 and C2, and a plurality of second input-side switches SWj (j: 2 or 14) to be connected to the connecting terminal A3 arranged between the capacitors C1 and C2.

The first input-side switches SWi connect the independent terminals A1 and A2 of the capacitors C1 and C2, respectively, to the electrode terminals (corresponding to first electrode terminals) that are arranged at a predetermined interval that covers a predetermined number of the electrode terminals (one electrode terminal in the present embodiment) corresponding to the number of connecting terminals A3 (one connecting terminal in the present embodiment) arranged between the capacitors C1 and C2, among the electrode terminals T1 to T15 of the battery cells V1 to V14.

Specifically, the first input-side switches SWi of the present embodiment are connected to the electrode terminals (first electrode terminals) T1, T3, T5, T7, T9, T11, T13 and T15, among the electrode terminals T1 to T15 of the battery cells V1 to V14, which are arranged at a predetermined interval that covers one electrode terminal corresponding to one connecting terminal A3.

In the present embodiment, of the first input-side switches SWi, the input-side switches SW3, SW7, SW11 and SW15 are connected to the independent terminal A1 of the first capacitor C1. These input-side switches SW3, SW7, SW11 and SW15 are connected to the electrode terminals T3, T7, T11 and T15, respectively, which correspond to the [4m−1]^{th} (positive integer) electrode terminals when the electrode terminals T1 to T15 of the battery cells V1 to V14 are counted in ascending order of the potential.

Also, in the present embodiment, of the first input-side switches SWi, the input-side switches SW1, SW5, SW9 and SW13 are connected to the independent terminal A2 of the second capacitor C2. These input-side switches SW1, SW5, SW9 and SW13 are connected to the electrode terminals T1,15, T9 and T13, respectively, which correspond to the [4m−3]^{6h} (positive integer) electrode terminals.

The second input-side switches SWj connect the connecting terminal A3 arranged between the capacitors C1 and C2 to a part (corresponding to second electrode terminals) of the electrode terminals other than those which are connected with the first input-side switches SWi, among the electrode terminals T1 to T15 of the battery cells V1 to V14.

The number of the second input-side switches SWj (SW2 and SW14) is less than the number of the electrode terminals other than those which are connected with the first-input side switches SWi. Specifically, the second input-side switches SWj of the present embodiment are connected to the electrode terminal (second electrode terminal) T14 of the high-voltage-side cell V14 and the electrode terminal (second electrode terminal) T2 of the low-voltage-side cell V1, among the battery cells V1 to V14.

The input-side switches SW1 to SW15 are semiconductor switches whose on-state and off-state are switched according to a command signal that is generated under the control of the microcomputer 25 described later.

For example, let us suppose that charge voltages of the battery cells V1 and V2 are applied to the first and second capacitors C1 and C2, respectively. In this case, the microcomputer 25 concurrently turns on the first input-side switches SW1 and SW3 and the second input-side switch SW2 of the input-side connection switching circuit 21.

Thus, the electrode terminals T1 and T2 of the battery cell V1 are connected to both ends (the independent terminal A2 and the connecting terminal A3) of the second capacitor C2, and the electrode terminals T2 and T3 of the battery cell V2 are connected to both ends (the independent terminal A1 and the connecting terminal A3) of the first capacitor C1. Accordingly, a charge voltage of the battery cell V1 is applied to the second capacitor C2 and a charge voltage of the battery cell V2 is applied to the first capacitor C1.

Further, let us suppose that charge voltages of the battery cells (unconnected battery cells) V3 to V12 among the battery cells V1 to V14, whose electrode terminals are not connected with the second input-side switches, are applied to the first and second capacitors C1 and C2. In this case, the microcomputer 25 turns on the first input-side switches that are connected to the electrode terminals of an unconnected battery cell targeted to voltage detection and a battery cell close to the unconnected battery cell (including unconnected battery cells not targeted to voltage detection).

Thus, the electrode terminal of the unconnected battery cell targeted to voltage detection and the battery cell close to the unconnected battery cell are connected to the independent terminals A1 and A2 of the capacitors C1 and C2, respectively. Accordingly, the charge voltages of the unconnected battery cell and the battery cell close to the unconnected battery cells are collectively applied to the capacitors C1 and C2.

For example, let us suppose that the charge voltage of the battery cell V3, i.e. an unconnected battery cell, is applied to the first and second capacitors C1 and C2. In this case, the microcomputer 25 concurrently turns on the first input-side switches SW3 and SW5 which are connected to the electrode terminal T3 of the battery cell V3 and the electrode terminal T5 of the battery cell V4 close to the battery cell V3.

Thus, the electrode terminal T3 of the battery cell V3 is connected to the independent terminal A1 of the first capacitor C1, and the electrode terminal T5 of the battery cell V4 is connected to the independent terminal A2 of the second capacitor C2. Accordingly, the charge voltages of the battery cells V3 and V4 are collectively applied to the capacitors C1 and C2, respectively.

The capacitor circuit 22 is configured by the pair of capacitors C1 and C2 connected in series. The capacitors C1 and C2 used here have the same electrostatic capacitance. In the capacitor circuit 22, the connecting point that connects between the capacitors C1 and C2 configures the connecting terminal A3 and the points, each of which is opposed to the connecting point A3, configure the independent terminals A1 and A2.

The output-side connection switching circuit 23 is a switching circuit that connects the independent terminals A1 and A2 and the connecting terminal A3 of the pair of capacitors C1 and C2 to first to third input terminals B1 to B3, respectively, provided in the voltage detecting circuit 24.

With the activation of the output-side connection switching circuit 23, the stored charged voltage (amount of charge) of at least one of the capacitors C1 and C2 is ensured to be applied to the input terminals B1 to B3 of the voltage detecting circuit 24.

In the present embodiment, the output-side connection switching circuit 23 has a first output-side switch SW16 to be connected to the independent terminal A1 of the first capacitor C1, a second output-side switch SW17 to be connected to the independent terminal A2 of the second capacitor C2, and a third output-side switch SW18 to be connected to the connecting terminal A3 arranged between the capacitors C1 and C2.

The first output-side switch SW16 is a switch that connects the independent terminal A1 of the first capacitor C1 to the first input terminal B1 of the voltage detecting circuit 24. The second output-side switch SW17 is a switch that connects the independent terminal A2 of the second capacitor C2 to the second output terminal B2 of the voltage detecting circuit 24. The third output-side switch SW18 is a switch that connects the connecting terminal A3 arranged between the capacitors C1 and C2 to the third input terminal B3 of the voltage detecting circuit 24.

The output-side switches SW16 to SW18 are semiconductor switches whose on-state and off-state are switched according to a command signal generated under the control of the microcomputer 25 described later.

For example, let us suppose that the stored voltages of the first and second capacitors C1 and C2 are separately applied to the voltage detecting circuit 24. In this case, the microcomputer 25 turns on the output-side switches SW16 to SW18 of the output-side connection switching circuit 23.

Thus, the first input terminal B1 is connected to the independent terminal A1 of the first capacitor C1, the second input terminal B2 is connected to the independent terminal A2 of the second capacitor C2, and the third input terminal B3 is connected to the connecting terminal A3 arranged between the capacitors C1 and C2. Accordingly, the stored voltages of the capacitors C1 and C2 are separately applied to the voltage detecting circuit 24.

In collectively applying the stored voltages of the capacitors C1 and C2 to the voltage detecting circuit 24, the microcomputer 25 turns on the output-side switches SW16 and SW17 of the output-side connection switching circuit 23.

Thus, the first input terminal B1 of the voltage detecting circuit 24 is connected to the independent terminal A1 of the first capacitor C1, while the second input terminal B2 of the voltage detecting circuit 24 is connected to the independent terminal A2 of the second capacitor C2. Accordingly, the stored voltages of the capacitors C1 and C2 are collectively applied to the voltage detecting circuit 24.

In applying only the stored voltage of the first capacitor C1 to the voltage detecting circuit 24, the microcomputer 25 may only have to turn on the output-side switches SW16 and SW18 of the output-side connection switching circuit 23. Further, in applying only the stored voltage of the second capacitor C2 to the voltage detecting circuit 24, the microcomputer 25 may only have to turn on the output-side switches SW17 and SW18 of the output-side connection switching circuit 23.

The voltage detecting circuit 24 having the first, second and third input terminals B1, B2 and B2 serve as a voltage detecting means or unit (including a voltage detector) that detects the voltages between the input terminals B1 to B3.

In the present embodiment, the voltage detecting circuit 24 includes a first differential voltage detecting section 241 that detects a voltage across the first and third input terminals B1 and B3, a second differential voltage detecting section 242 that detects a voltage across the second and third input terminals B2 and B3, and a third differential voltage detecting section 243 that detects a voltage across the first and second input terminals B1 and B2.

In the present embodiment, the first and second differential voltage detecting sections 241 and 242 are provided for the capacitors C1 and C2, respectively, to configure a plurality of separate voltage detecting sections that separately detect the stored voltages of the capacitors. The third differential voltage detecting section 243 configures a collective voltage detecting section that collectively detects the stored voltages of the capacitors C1 and C2.

In the present embodiment, the first differential voltage detecting section 241 is configured by a differential amplifier circuit that amplifies and outputs the stored voltage of the first capacitor C1 at a predetermined amplification factor (first amplification factor). The second differential voltage detecting section 242 is configured by a differential amplifier circuit that amplifies and outputs the stored voltage of the second capacitor C2 at a predetermined amplification factor (first amplification factor).

In the present embodiment, the third differential voltage detecting section 243 is configured by a differential amplifier circuit that amplifies and outputs the stored voltages of the capacitors C1 and C2 at a predetermined second amplification factor that is different from the first amplification factor.

The differential voltage detecting sections 241 to 243 are provided with respective AD converters, not shown. Thus, the differential voltage detecting sections 241 to 243 are ensured to convert voltage signals (analogue signals) inputted via the input terminals B1 to B3 to digital signals and output the converted signals to the microcomputer 25.

The microcomputer 25 includes a CPU (central processing unit) and a memory that configures a storing means. The microcomputer 25 serves as a control unit (corresponding to control means or a controller) that executes various processings according to a program stored in the memory.

The microcomputer 25 is configured to control the operation of (turn on/off the switches of) the input-side connection switching circuit 21 and the output-side connection switching circuit 23. At the same time, the microcomputer 25 is configured to execute a voltage diagnosing process, for example, to diagnose the state of the voltages of the battery cells V1 to V14 that configure the battery pack 1, on the basis of the signals outputted from the voltage detecting circuit 24.

Specifically, in the present embodiment, the microcomputer 25 is configured to turn on the input-side switches of the input-side connection switching circuit 21 according to a sequence stored in the memory. Thus, the voltage of at least one battery cell is ensured to be applied to the capacitors.

Further, the microcomputer 25 is ensured to turn on the output-side switches SW16 to SW18 of the output-side connection switching circuit 23 according to a sequence stored in the memory. Thus, at least two of the independent terminals A1 and A2 and the connecting terminal A3 of the capacitors C1 and C2 are connected to the input terminals B1 to B3, so that the stored voltage of at least one of the capacitors C1 and C2 is ensured to be applied to the input terminals B1 to B3.

In the present embodiment, the microcomputer 25 has a configuration for controlling the activation of the input-side connection switching circuit 21, the configuration serving as an input-side switch control unit 25a (corresponding to input-side switch control means or a input-side switch controller). Further, the microcomputer 25 has a configuration for controlling the activation of the output-side connection switching circuit 23, the configuration serving as an output-side switch control unit 25b (corresponding to output-side switch control means or a input-side switch controller).

Hereinafter is described the operation of the voltage monitoring device 2 of the present embodiment. In the present embodiment, a specific operation example is provided, in which voltages of representative four battery cells V1 to V4 are monitored by using the pair of capacitors C1 and C2. In this operation example, the battery cells are monitored in ascending order of voltage of the battery cell, i.e. in the order of V1, V2, V3, V4, etc.

First, the microcomputer 25 turns on the first and second input-side switches Sw1 to SW3 of the input-side connection switching circuit 21.

When the input-side switches SW1 and SW2 are turned on, the second capacitor C2 is connected to the electrode terminals T1 and T2 of the battery cell V1 to thereby charge the second capacitor C2. Thus, the voltage of the second capacitor C2 becomes equal to that of the battery cell V1.

When the input-side switches SW2 and SW3 are turned on, the first capacitor C1 is connected to the electrode terminals T2 and T3 of the battery cell V2 to thereby charge the first capacitor C1. Thus, the voltage of the first capacitor C1 becomes equal to that of the battery cell V2.

After that, the microcomputer 25 turns off the input-side switches SW1 to SW3 of the input-side connection switching circuit 21, while turning on the output-side switches SW16 to SW18 of the output-side connection switching circuit 23.

When the first and third output-side switches SW16 and SW18 are turned on, the first capacitor C1 is connected to the first differential voltage detecting section 241 via the first and third input terminals B1, B3 of the voltage detecting circuit 24. Then, the first differential voltage detecting section 241 amplifies the voltage of the first capacitor C1 having a voltage equal to that of the battery cell V2 at the first amplification factor and outputs the amplified voltage to the microcomputer 25.

When the second and third output-side switches SW17 and SW18 are turned on, the second capacitor C2 is connected to the second differential voltage detecting section 242 via the second and third input terminals B2 and B3 of the voltage detecting circuit 24. Then, the second differential voltage detecting section 242 amplifies the voltage of the second capacitor C2 having a voltage equal to that of the battery cell V1 at the first amplification factor and outputs the amplified voltage to the microcomputer 25.

The microcomputer 25 detects the voltages of the battery cells V1 and V2 on the basis of the signals outputted from the voltage detecting circuit 24. Based on the detected voltages, the microcomputer 25 executes the voltage diagnosing process to diagnose the occurrence of abnormality, such as overcharge/overdischarge or deterioration, of the battery cells V1 and V2.

Then, the microcomputer 25 tunes on the input-side switches SW3 and SW5. Thus, the independent terminals A1 and A2 of the first and second capacitors C1 and C2 are connected to the electrode terminal T3 of the battery cell V3 and the electrode terminal T5 of the battery cell V4 to thereby collectively charge the capacitors C1 and C2. As a result, the voltages of the capacitors C1 and C2 become equal to the sum of the voltages of the battery cells V3 and V4.

After that, the microcomputer 25 turns off the input-side switches SW3 and SW5, while turning on the first and second output-side switches SW16 and SW17 of the output-side connection switching circuit 23.

When the first and second output-side switches SW16 and SW17 are turned on, the capacitors C1 and C2 are connected to the third differential voltage detecting section 243 via the first and second input terminals B1 and B2, respectively, of the voltage detecting circuit 24. Then, the third differential voltage detecting section 243 collectively amplifies the voltages of the capacitors C1 and C2 at the second amplification factor and outputs the amplified voltages to the microcomputer 25.

Based on the signals outputted from the voltage detecting circuit 24, the microcomputer 25 detects the voltage of a battery block configured by the battery cells V3 and V4 (sum of the voltages of the battery cells V3 and V4). As a result, the microcomputer 25 executes the voltage diagnosing process to diagnose the occurrence of abnormality, such as overcharge/overdischarge or deterioration, of the battery block configured by the battery cells V3 and V4.

In monitoring the voltages of the battery cells V5 to V12 subsequent to the battery cells V3 and V4, the microcomputer 25 turns on or off the first input-side switches that are connected to the electrode terminals of the battery cells V5 to V12 and the second output-side switches SW16 and SW17 of the output-side connection switching circuit 23. Thus, the microcomputer 25 is able to collectively detect the voltages of the adjacent battery cells.

Monitoring of the voltages of the battery cells V13 and V14 is performed in a manner similar to the monitoring of the battery cells V1 and V2. Specifically, the microcomputer 25 turns on or off the input-side switches SW13 to SW15 connected to the electrode terminals T13 to T15 of the battery cells V13 to V14, and the output-side switches SW16 to SW18 of the output-side connection switching circuit 23. Thus, the microcomputer 25 is able to separately detect the voltages of the battery cells V13 and V14.

According to the voltage monitoring device 2 of the present embodiment, the total number of the first and second input-side switches that require high withstand-voltage properties is less than the total number of the electrode terminals T1 to T15 of the battery cells V1 to V14. Therefore, the number of parts can be reduced in the components configuring the voltage monitoring device 2 that uses a flying capacitor method. As a result, the cost incurred in the entire voltage monitoring device 2 can be reduced.

Of the battery cells V1 to V14, the battery cells V3 to V12 are unconnected. Specifically, the battery cells V3 to V12 having the electrode terminals T4, T6, T8, T10 and T12 are not connected with the second input-side switches SWj. For example, when the first input-side switches connected to the electrode terminals of a battery cell close to the unconnected battery cell are turned on, the voltages of the unconnected battery cell and the battery cell close to the unconnected battery cell can be collectively detected.

Further, as in the embodiment described above, only the number of the second input-side switches connected to the connecting terminal A3 may be reduced without reducing the number of the first input-side switches connected to the independent terminals A1 and A2 of the capacitors C1 and C2, respectively. With this configuration, in collectively detecting the voltages of a plurality of battery cells, the capacitors C1 and C2 may be permitted to function as a single charging means.

With this configuration, it is not necessary to provide a capacitor which is dedicated to collective detection of the voltages of a plurality of battery cells. Accordingly, the number of parts can be reduced in the components configuring the voltage monitoring device 2 that uses a flying capacitor method.

In the embodiment described above, the voltage detecting circuit 24 is used. The voltage detection circuit 24 includes the third differential voltage detecting section 243 that collectively detects the stored voltages of the capacitors C1 and C2. The third differential voltage detecting section 243 performs the collective detection separately from the first and second differential voltage detecting sections 241 and 242.

With this configuration, depending on whether the stored voltages of the capacitors C1 and C2 are collectively detected or separately detected, the amplification factor for the inputted voltage can be changed or the internal resistance or the like can be changed according to the inputted voltage. Thus, this configuration can easily increase the voltage range that can be detected by the voltage detecting circuit 24.

### Second Embodiment

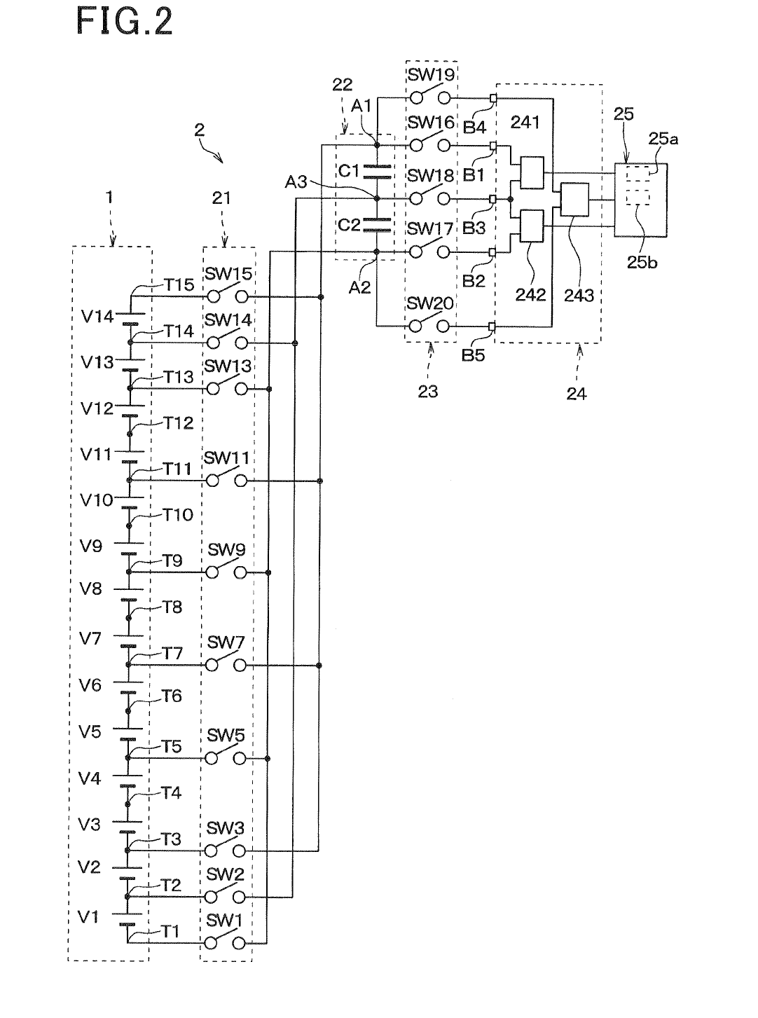

Referring to FIG. 2, hereinafter is described a second embodiment of the present invention. The second embodiment is different from the first embodiment in that the circuit configurations of the output-side connection switching circuit 23 and the voltage detecting circuit 24 have been changed.

As shown in FIG. 2, in the present embodiment, the output-side connection switching circuit 23 is additionally provided with fourth and fifth output-side switches SW19 and SW20, compared to the first embodiment. Further, the voltage detecting circuit 24 is additionally provided with fourth and fifth input terminals B4 and B5, compared to the first embodiment.

The fourth output-side switch SW19 is connected to the independent terminal A1 of the first capacitor C1 and the fourth input terminal B4 of the voltage detecting circuit 24. In other words, the fourth output-side switch SW19 is a switch that connects the independent terminal A1 of the first capacitor C1 to the fourth input terminal B4.

The fifth output-side switch SW20 is connected to the independent terminal A2 of the second capacitor C2 and the fifth input terminal B5 of the voltage detecting circuit 24. In other words, the fifth output-side switch SW20 is a switch that connects the independent terminal A2 of the second capacitor C2 to the fifth input terminal B5. The fourth and fifth input terminals B4 and B5 of the voltage detecting circuit 24 are connected to the third differential voltage detecting section 243. Thus, the differential voltage detecting section 243 is collectively applied with the voltages of the capacitors C1 and C2 via the fourth and fifth input terminals B4 and B5, respectively.

In the present embodiment, in collectively apply the stored voltages of the capacitors C1 and C2 to the voltage detecting circuit 24, the microcomputer 25 turns on the fourth and fifth output-side switches SW19 and SW20 of the output-side connection switching circuit 23.

Thus, the independent terminal A1 of the first capacitor C1 is connected to the fourth input terminal B4 of the voltage detecting circuit 24. At the same time, the independent terminal A2 of the second capacitor C2 is connected to the fifth input terminal B5 of the voltage detecting circuit 24. Thus, the stored voltages of the capacitors C1 and C2 are collectively applied to the voltage detecting circuit 24.

The configuration other than the above is similar to the first embodiment. In the configuration of the present embodiment as well, the total number of the first and second input-side switches is less than the total number of the electrode terminals T1 to T15 of the battery cells V1 to V14. Thus, the number of parts can be reduced in the components configuring the voltage monitoring device 2 that uses a flying capacitor method.

### (Modifications)

The present invention is not limited to the embodiments described above, but may be modified, as appropriated, within a range not departing from the spirit of the present invention. For example, the present invention may be variously modified as set forth below.

(1) In the embodiments described above, the first input-side switches SWi are connected to the odd-number-order electrode terminals (first electrode terminals) T1, T3, T5, T7, T9, T11, T13 and T15, while the second input-side switches SWj are connected to the even-number-order electrode terminals (second electrode terminals) T2 and T14. However, no limitation shall be imposed by this.

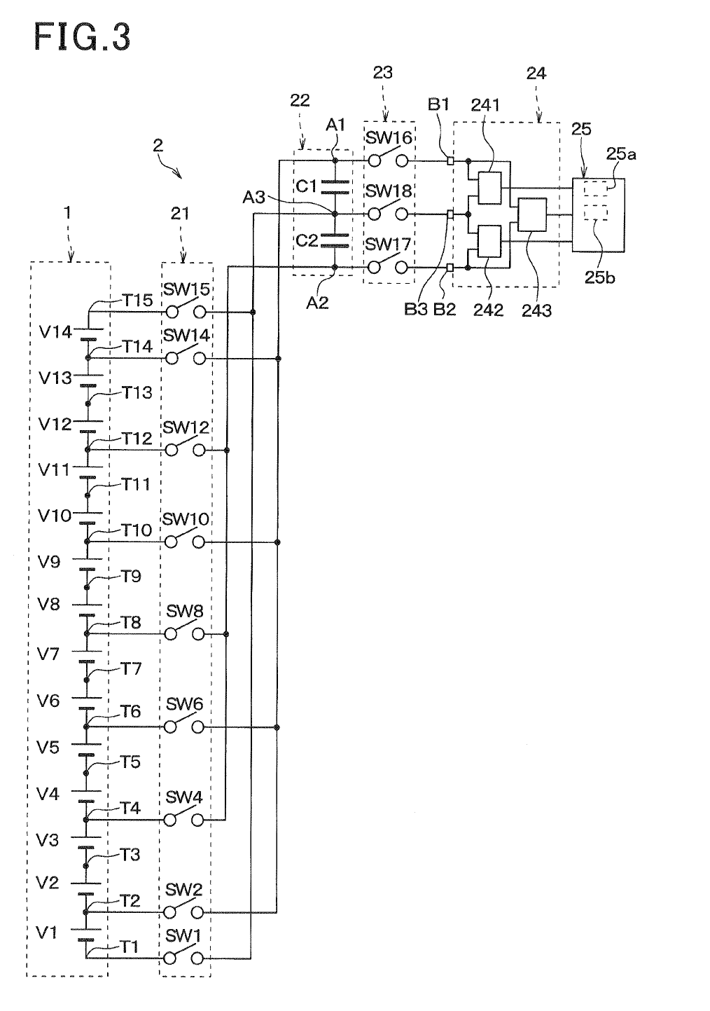

The first input-side switches SWi may only have to be connected to the electrode terminals arranged at a predetermined interval that covers a predetermined number of the electrode terminals corresponding to the number of the connecting terminals A3 arranged between the capacitors C1 and C2, among the electrode terminals T1 to T15 of the battery cells V1 to V14. For example, if only the above condition is met, as shown in FIG. 3, the first input-side switches SWi may be connected to the even-number-order electrode terminals T2, T4, T6, T8, T10, T12 and T14, while the second input-side switches SWj may be connected to the odd-number-order electrode terminals T1 and T15.

(2) In the embodiments described above, the voltage monitoring device 2 is applied to the battery pack 1 in which an even number of battery cells are connected in series. However, no limitation shall be imposed by this.

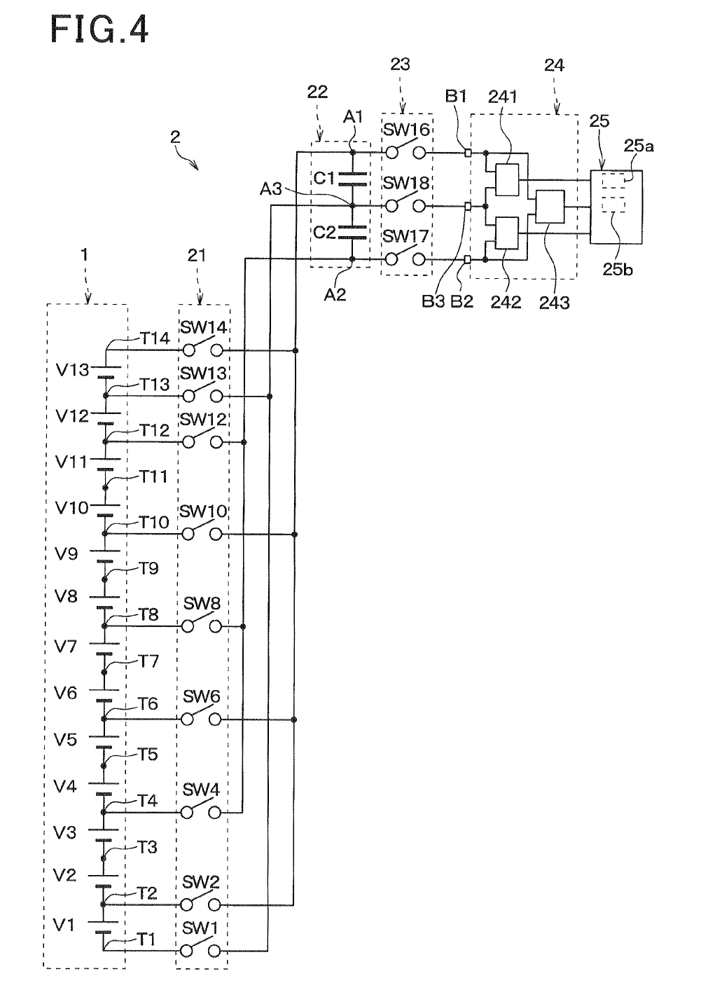

For example, as shown in FIG. 4, the voltage monitoring device 2 may be applied to the battery pack 1 in which an odd number of battery cells are connected in series. In this case, thirteen battery cells V1 to V13 are connected in series to one another. Among them, twelve battery cells V2 to V13 can configure six pairs of adjacent battery cells V2 and V3, V4 and V5, V6 and V7, V8 and V9, V10 and V11, and V12 and V13, but one battery cell V1 cannot configure these pairs. Thus, the battery cells V2 to V13 may be monitored using the pair of the capacitors C1 and C2, and one battery cell V1 may be monitored using either one of the pair of the capacitors C1 and C2 (e.g., the first capacitor C1 in FIG. 4).

(3) In the embodiments described above, the second input-side switches SWj are only connected to both of the electrode terminal of the high-voltage-side cell and the electrode terminal of the low-voltage-side cell. However, no limitation shall be imposed by this. The number of the second input-side switches SWj may only have to be less than the number of the electrode terminals other than those which are connected with the first input-side switches SWi, among the electrode terminals T1 to T15 of the battery cells V1 to V14. If only this condition is met, the second input-side switches SWj may be connected to the electrode terminals other than those of the high-voltage-side cell and the low-voltage-side cell.

(4) As in the embodiments described above, the second input-side switches SWj may desirably be connected to both of the electrode terminal of the high-voltage-side cell and the electrode terminal of the low-voltage-side cell. Alternative to this, if the voltage of only a part of the battery cells has to be detected, for example, the second input-side switches SWj may be connected to the electrode terminals other than those of the high-voltage-side cell and the low-voltage-side cell.

(5) In the embodiments described above, the capacitor circuit 22 is configured by the pair of serially connected capacitors C1 and C2. However, no limitation shall be imposed by this. The capacitor circuit 22 may be configured by serially connected three or more capacitors, on condition that the first input-side switches SWi are connected to the electrode terminals arranged at a predetermined interval that covers a predetermined number of the electrode terminals corresponding to corresponding to the number of connecting terminals arranged between the capacitors, among the electrode terminals T1 to T15 of the battery cells V1 to V14.

(6) In the embodiments described above, the voltage monitoring device 2 is applied, as a specific example, to the battery pack 1 in which fourteen battery cells are connected in series. However, the number of battery cells that configure the battery pack 1, to which is the voltage monitoring device may be applied, is not limited to fourteen.

(7) In the embodiments described above, the voltage monitoring device 2 is applied to an in-vehicle high-voltage battery. However, the voltage monitoring device 2 may be applied to other batteries.

(8) In the embodiments described above, the elements that configure each of the embodiments are not necessarily essential, unless the elements are specifically defined to be essential and are apparently considered to be essential in principle. Further, in the embodiments described above, numerical values are referred to, such as the number of components, and the numerical values, amounts and ranges related to the components. However, these numerical values are not limited to those specified in the embodiments, unless the numerical values are specifically defined to be essential and are apparently considered to be essential in principle.

What is claimed is:

1. A voltage monitoring device for monitoring voltage of a battery pack using a flying capacitor method, the battery pack including a plurality of battery cells connected in series to each other, the voltage monitoring device comprising:
a capacitor circuit that includes a pair of independent terminals, a plurality of capacitors connected in series to each other between the pair of independent terminals, and at least one connecting terminal arranged between adjacent capacitors of the plurality of capacitors;
a plurality of first input-side switches that connect the pair of independent terminals to first electrode terminals among electrode terminals of the plurality of battery cells, the first electrode terminals being arranged at a predetermined interval that covers a predetermined number of the electrode terminals corresponding to a number of the connecting terminals;
a plurality of second input-side switches that connect the connecting terminal to second electrode terminals among the electrode terminals other than the first electrode terminal, a number of the second input-side switches being less than a number of the electrode terminals other than the first electrode terminals;
input-side switch control means that controls the plurality of first input-side switches and the plurality of second input-side switches so as to be turned on in a predetermined sequence, thereby applying voltage of at least one of the plurality of battery cells to the plurality of capacitors;
voltage detecting means that includes a plurality of input terminals and detects voltage between the plurality of input terminals;
a plurality of output-side switches that connect the plurality of input terminals to the pair of independent terminals and the connecting terminal; and
output-side switch control means that controls the plurality of output-side switches so as to be turned on in a predetermined sequence to connect the plurality of input terminals to at least two of the connecting terminal and the pair of independent terminals, thereby applying stored voltage of at least one of the plurality of capacitors to the plurality of input terminals of the voltage detecting means.

2. The voltage monitoring device according to claim 1, wherein:
the plurality of battery cells include:
a high-voltage side battery cell that is a battery cell located at highest voltage side among the plurality of battery cells; and
a low-voltage side battery cell that is a battery cell located at lowest voltage side among the plurality of battery cells,
one of the first input-side switches and the second input-side switches are connected to at least an electrode terminal of the high-voltage side battery cell and an electrode terminal of the low-voltage side battery cell.

3. The voltage monitoring device according to claim 2, wherein:
the voltage detecting means includes:
a plurality of separate voltage detecting sections that are provided with respect to each of the capacitors and separately detect stored voltage of each of the capacitors; and
a collective voltage detecting section that collectively detects stored voltage of each of the capacitors.

4. The voltage monitoring device according to claim 3, wherein:
the plurality of separate voltage detecting sections are configure to amplify stored voltage of the plurality of capacitors at a predetermined first amplification factor to output amplified voltage; and
the collective voltage detecting section is configured to amplify stored voltage of the plurality of capacitors at a predetermined second amplification factor to output amplified voltage, the second amplification factor being an amplification factor that is predetermined to be different from the first amplification factor.

5. The voltage monitoring device according to claim 1, wherein:
the voltage detecting means includes:
a plurality of separate voltage detecting sections that are provided with respect to each of the capacitors and separately detect stored voltage of each of the capacitors; and
a collective voltage detecting section that collectively detects stored voltage of each of the capacitors.

6. The voltage monitoring device according to claim 5, wherein:
the plurality of separate voltage detecting sections are configure to amplify stored voltage of the plurality of capacitors at a predetermined first amplification factor to output amplified voltage; and
the collective voltage detecting section is configured to amplify stored voltage of the plurality of capacitors at a predetermined second amplification factor to output amplified voltage, the second amplification factor being an amplification factor that is predetermined to be different from the first amplification factor.

7. The monitoring system according to claim 1, wherein:
the battery pack is configured to supply electrical power to an electric motor mounted in a vehicle.

8. A monitoring system, comprising:
a battery pack including a plurality of battery cells connected in series to each other; and
a voltage monitoring device that monitors voltage of a battery pack using a flying capacitor method and includes:
a capacitor circuit that includes a pair of independent terminals, a plurality of capacitors connected in series to each other between the pair of independent terminals, and at least one connecting terminal arranged between adjacent capacitors of the plurality of capacitors;
a plurality of first input-side switches that connect the pair of independent terminals to first electrode terminals among electrode terminals of the plurality of battery cells, the first electrode terminals being arranged at a predetermined interval that covers a predetermined number of the electrode terminals corresponding to a number of the connecting terminals;
a plurality of second input-side switches that connect the connecting terminal to second electrode terminals among the electrode terminals other than the first electrode terminal, a number of the second input-side switches being less than a number of the electrode terminals other than the first electrode terminals;
input-side switch control means that controls the plurality of first input-side switches and the plurality of second input-side switches so as to be turned on in a predetermined sequence, thereby applying voltage of at least one of the plurality of battery cells to the plurality of capacitors;
voltage detecting means that includes a plurality of input terminals and detects voltage between the plurality of input terminals;
a plurality of output-side switches that connect the plurality of input terminals to the pair of independent terminals and the connecting terminal; and
output-side switch control means that controls the plurality of output-side switches so as to be turned on in a predetermined sequence to connect the plurality of input terminals to at least two of the connecting terminal and the pair of independent terminals, thereby applying stored voltage of at least one of the plurality of capacitors to the plurality of input terminals of the voltage detecting means.

9. The monitoring system according to claim 8, wherein:
the plurality of battery cells include:
a high-voltage side battery cell that is a battery cell located at highest voltage side among the plurality of battery cells; and
a low-voltage side battery cell that is a battery cell located at lowest voltage side among the plurality of battery cells,
one of the first input-side switches and the second input-side switches are connected to at least an electrode terminal of the high-voltage side battery cell and an electrode terminal of the low-voltage side battery cell.

10. The monitoring system according to claim 9, wherein:
the voltage detecting means includes:
a plurality of separate voltage detecting sections that are provided with respect to each of the capacitors and separately detect stored voltage of each of the capacitors; and
a collective voltage detecting section that collectively detects stored voltage of each of the capacitors.

11. The monitoring system according to claim 10, wherein:
the plurality of separate voltage detecting sections are configure to amplify stored voltage of the plurality of capacitors at a predetermined first amplification factor to output amplified voltage; and
the collective voltage detecting section is configured to amplify stored voltage of the plurality of capacitors at a predetermined second amplification factor to output amplified voltage, the second amplification factor being an amplification factor that is predetermined to be different from the first amplification factor.

12. The monitoring system according to claim 8, wherein:
the voltage detecting means includes:
a plurality of separate voltage detecting sections that are provided with respect to each of the capacitors and separately detect stored voltage of each of the capacitors; and
a collective voltage detecting section that collectively detects stored voltage of each of the capacitors.

13. The monitoring system according to claim 12, wherein:
the plurality of separate voltage detecting sections are configure to amplify stored voltage of the plurality of capacitors at a predetermined first amplification factor to output amplified voltage; and
the collective voltage detecting section is configured to amplify stored voltage of the plurality of capacitors at a predetermined second amplification factor to output amplified voltage, the second amplification factor being an amplification factor that is predetermined to be different from the first amplification factor.

14. The monitoring system according to claim 7, wherein:
the battery pack is configured to supply electrical power to an electric motor mounted in a vehicle.

15. A voltage monitoring method for monitoring voltage of a battery pack using a flying capacitor method, the battery pack including a plurality of battery cells connected in series to each other, the voltage monitoring method comprising:
(i) providing a voltage monitoring device that monitors voltage of a battery pack using a flying capacitor method and includes:
a capacitor circuit that includes a pair of independent terminals, a plurality of capacitors connected in series to each other between the pair of independent terminals, and at least one connecting terminal arranged between adjacent capacitors of the plurality of capacitors;
a plurality of first input-side switches that connect the pair of independent terminals to first electrode terminals among electrode terminals of the plurality of battery cells, the first electrode terminals being arranged at a predetermined interval that covers a predetermined number of the electrode terminals corresponding to a number of the connecting terminals;
a plurality of second input-side switches that connect the connecting terminal to second electrode terminals among the electrode terminals other than the first electrode terminal, a number of the second input-side switches being less than a number of the electrode terminals other than the first electrode terminals;
input-side switch control means that controls the plurality of first input-side switches and the plurality of second input-side switches;
voltage detecting means that includes a plurality of input terminals;
a plurality of output-side switches that connect the plurality of input terminals to the pair of independent terminals and the connecting terminal;
output-side switch control means that controls the plurality of output-side switches,
(ii) controlling, by the input-side switch control means, the plurality of first input-side switches and the plurality of second input-side switches so as to be turned on in a predetermined sequence, thereby applying voltage of at least one of the plurality of battery cells to the plurality of capacitors;
(iii) controlling, by the output-side switch control means, the plurality of output-side switches so as to be turned on in a predetermined sequence to connect the plurality of input terminals to at least two of the connecting terminal and the pair of independent terminals, thereby applying stored voltage of at least one of the plurality of capacitors to the plurality of input terminals of the voltage detecting means; and
(iv) detecting, by the voltage detecting means, voltage between the plurality of input terminals.
